(19) United States
(12) Patent Application Publication
(10) Pub. No.: US 2026/0255599 A1
(43) Pub. Date: Aug. 27, 2026

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Dae Sung EOM, Gyeonggi-do (KR)

(21) Appl. No.: 19/228,749

(22) Filed: Jun. 5, 2025

(30) Foreign Application Priority Data
Feb. 25, 2025 (KR) 10-2025-0024532

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

A semiconductor device includes a stack including first insulating layers and second insulating layers that are alternately stacked; channel structures extending through the stack; and gate lines disposed between the channel structures and the first insulating layers and including annular portions respectively surrounding the channel structures and line portions connecting the annular portions to each other.

### CROSS-REFERENCE TO RELATED APPLICATION

This application claims priority under 35 U.S.C. §119 to Korean Patent Application No. 10-2025-0024532 filed on February 25, 2025, which is incorporated herein by reference in its entirety.

### BACKGROUND

### 1. Technical Field

Embodiments of the present disclosure relate to an electronic device, and more particularly, to a semiconductor device and a method of manufacturing the semiconductor device.

### 2. Related Art

The degree of integration of a semiconductor device is primarily determined by the area occupied by a unit memory cell. Recently, as advancements in the degree of integration of a semiconductor device for forming memory cells in a single layer on a substrate approach a limit, three-dimensional (“3-D”) semiconductor devices, which stack memory cells in many layers over a substrate, have been proposed. Furthermore, for further enhancing the operational reliability and/or performance characteristics of 3-D semiconductor devices, various structures and manufacturing methods are presently under development.

### SUMMARY

It is an object of the present invention to provide a 3-D semiconductor device having exhibiting improved operational reliability.

It is another object of the present invention to provide a 3-D semiconductor device exhibiting at least one improved performance characteristic. Hereinafter the 3-D semiconductor device according to the embodiments of the present disclosure will be referred to simply as a semiconductor device.

Accordingly, in an embodiment of the present disclosure, a semiconductor device may include a stack including first insulating layers and second insulating layers that are alternately stacked; channel structures extending through the stack; and gate lines disposed between the channel structures and the first insulating layers and including annular portions respectively surrounding the channel structures and line portions connecting the annular portions to each other.

In another embodiment of the present disclosure, a semiconductor device may include first channel structures arranged in a first direction and a second direction intersecting the first direction; first word lines including first annular portions respectively surrounding the first channel structures and first line portions connecting the first annular portions to each other and stacked along sidewalls of the first channel structures; second channel structures arranged in the first direction and the second direction; second word lines including second annular portions respectively surrounding the second channel structures and second line portions connecting the second annular portions to each other and stacked along sidewalls of the second channel structures; a first pad stack including first word line pads connected to the first word lines; and a second pad stack including second word line pads connected to the second word lines.

In yet another embodiment of the present disclosure, a method of manufacturing a semiconductor device may include forming a stack including first insulating layers and second insulating layers that are alternately stacked; forming first openings extending through the stack; forming second openings by etching the first insulating layers through the first openings, the second openings surrounding the first openings; forming sacrificial layers in the first openings and the second openings; forming at least one trench in at least one of the sacrificial layers; forming third openings by etching the first insulating layers through the at least one trench, the third openings connecting the second openings to each other; and forming gate lines in the second openings and the third openings.

In yet another embodiment of the present disclosure, a method of manufacturing a semiconductor device may include forming a stack including first insulating layers and second insulating layers that are alternately stacked; forming first openings extending through a cell region of the stack; forming second openings by etching the first insulating layers through the first openings; forming third openings by etching the first insulating layers through the second openings, the third openings connecting adjacent second openings to each other; forming gate lines including annular portions disposed in the second openings and line portions disposed in the third openings; forming a slit in a pad region of the stack; and replacing the first insulating layers of the pad region with pads through the slit.

These and other embodiments, features, and advantages of the embodiments of the present disclosure will become better understood from the following drawings and detailed description.

### BRIEF DESCRIPTION OF THE DRAWINGS

FIGS. 1A to 1C are diagrams illustrating the structure of a semiconductor device in accordance with an embodiment of the present disclosure.

FIGS. 2A to 2C are diagrams illustrating the structure of a semiconductor device in accordance with an embodiment of the present disclosure.

FIGS. 3A and 3B are diagrams illustrating the structure of a semiconductor device in accordance with an embodiment of the present disclosure.

FIGS. 4A and 4B are diagrams illustrating the structure of a semiconductor device in accordance with an embodiment of the present disclosure.

FIG. 5 is a diagram illustrating the structure of a semiconductor device in accordance with an embodiment of the present disclosure.

FIG. 6 is a diagram illustrating the structure of a semiconductor device in accordance with an embodiment of the present disclosure.

FIG. 7 is a diagram illustrating the structure of a semiconductor device in accordance with an embodiment of the present disclosure.

FIGS. 8A, 9A, 10A, 11A, 12A, and 13A and FIGS. 8B, 9B, 10B, 11B, 12B, and 13B are diagrams for describing a method of manufacturing a semiconductor device in accordance with an embodiment of the present disclosure.

FIGS. 14A, 15A, 16A, 17A, and 18A and FIGS. 14B, 15B, 16B, 17B, and 18B are diagrams for describing a method of manufacturing a semiconductor device in accordance with an embodiment of the present disclosure.

FIG. 19 is a configuration diagram of a semiconductor device according to an embodiment of the present disclosure.

FIG. 20 is a configuration diagram of a semiconductor device according to an embodiment of the present disclosure.

### DETAILED DESCRIPTION

Various embodiments of the present disclosure are directed to a semiconductor device having a stable structure and improved characteristics and a method of manufacturing the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical spirit of the present disclosure will be described with reference to the accompanying drawings.

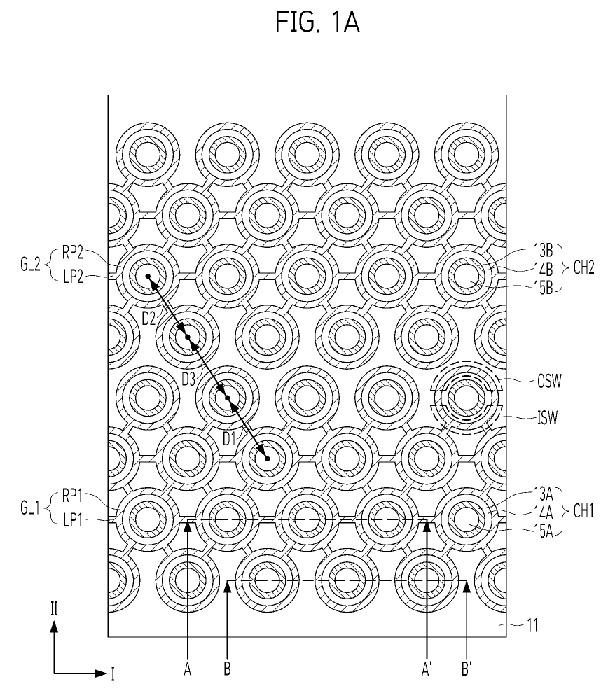

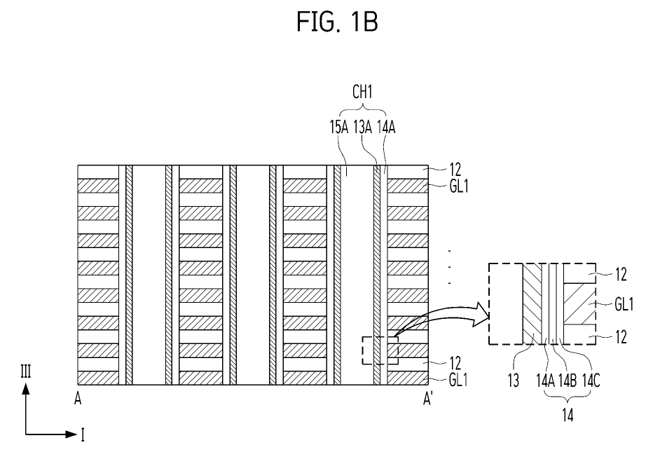

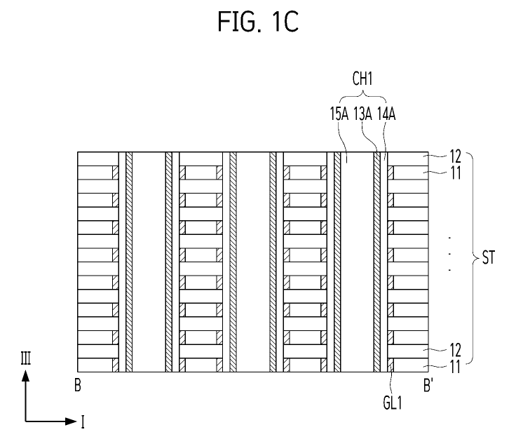

FIGS. 1A to 1C are diagrams illustrating the structure of a semiconductor device in accordance with an embodiment of the present disclosure. FIG. 1A is a plan view, FIG. 1B is a cross-sectional view taken along line A-A’ of FIG. 1A, and FIG. 1C is a cross-sectional view taken along line B-B’ of FIG. 1A.

Referring to FIGS. 1A to 1C, the semiconductor device may include a stack ST, first channel structures CH1, second channel structures CH2, first gate lines GL1, and second gate lines GL2. The stack ST may include first insulating layers 11 and second insulating layers 12 that are alternately stacked. The first insulating layers 11 may each include a material having a high etching selectivity with respect to the second insulating layers 12. For example, the first insulating layers 11 may each include a nitride, and the second insulating layers 12 may each include an oxide.

The first channel structures CH1 may extend through the stack ST. In a plane defined by a first direction I and a second direction II intersecting the first direction I, the first channel structures CH1 may be arranged in the first direction I and the second direction II. The first channel structures CH1 adjacent to each other in the second direction II may be staggered. In a cross section defined by the first direction I and a third direction III, the first channel structures CH1 may extend in the third direction III through the stack ST. The third direction III may be a direction intersecting the first direction I and the second direction II, and may be a vertical direction.

The first channel structure CH1 may include a first channel layer 13A, a first memory layer 14A, and a first insulating core 15A. The first memory layer 14A may surround sidewalls of the first channel layer 13A, and the first insulating core 15A may be disposed in the first channel layer 13A. The first memory layer 14A may include at least one of a tunneling layer, a data storage layer, and a blocking layer. The tunneling layer may surround the sidewalls of the first channel layer 13A, the data storage layer may surround the tunneling layer, and the blocking layer may surround the data storage layer. For example, the data storage layer may include a floating gate, polysilicon, nitride, a charge trap material, a variable resistance material, or the like. The blocking layer may include a high-k material, and may be a single layer or a multilayer layer.

The second channel structures CH2 may extend through the stack ST. The second channel structures CH2 may be arranged similarly to the first channel structures CH1, and may have a structure similar to that of the first channel structures CH1. The second channel structures CH2 may include a second channel layer 13B, a second memory layer 14B, and a second insulating core 15B.

A distance between the first channel structures CH1 spaced apart from each other and a distance between the second channel structures CH2 spaced apart from each other may be substantially the same as each other. A distance between the centers of the first channel structures CH1 adjacent to each other may be a first distance D1, and a distance between the centers of the second channel structures CH2 adjacent to each other may be a second distance D2. The first distance D1 and the second distance D2 may be substantially the same as each other. A third distance D3 between the centers of the first channel structure CH1 and the second channel structure CH2 adjacent to each other may be substantially the same as the first distance D1 and/or the second distance D2.

The first gate lines GL1 may be stacked along sidewalls of the first channel structures CH1. The first gate lines GL1 may be disposed between the first channel structures CH1 and the first insulating layers 11. The stacked first gate lines GL1 may be separated from each other by the second insulating layers 12.

The first gate line GL1 may include first annular portions RP1 and first line portions LP1. The first annular portions RP1 may surround the first channel structures CH1, respectively, and the first line portions LP1 may connect the first annular portions RP1 to each other. The first line portions LP1 may connect the first annular portions RP1 to each other in a radial shape and may also be referred to hereinafter as radial line portions.

In the illustrated embodiment, the first annular portions RP1 may be arranged to form hexagonal patterns. For example, a plurality of first annular portions RP1 may be disposed around one first annular portion RP1. One first annular portion RP1 may be disposed at the center of a hexagon, and six first annular portions RP1 may be disposed at six vertices of the hexagon, respectively. The first radial line portions LP1 may connect the first annular portions RP1 to each other in a radial shape by extending from the first annular portion RP1 located at the center to the first annular portions RP1 located at the vertices.

The first radial line portions LP1 may be disposed between the first annular portions RP1 facing each other. For example, outer sidewalls OSW of the first annular portions RP1 located at the outermost portions do not face the first annular portions RP1, and inner sidewalls ISW of the first annular portions RP1 located at the outermost portions face the first annular portions RP1. Accordingly, the first radial line portions LP1 may be connected to the inner sidewalls ISW of the first annular portions RP1 located at the outermost portions, but might not be connected to the outer sidewalls OSW of the first annular portions RP1 located at the outermost portions.

The second gate lines GL2 may be stacked along sidewalls of the second channel structures CH2. The second gate lines GL2 may be disposed between the second channel structures CH2 and the first insulating layers 11. The stacked second gate lines GL2 may be separated from each other by the second insulating layers 12. The first gate line GL1 and the second gate line GL2 located at the same layer may be separated from each other by the first insulating layer 11.

The second gate line GL2 may have a shape similar to that of the first gate line GL1. The second gate line GL2 may include second annular portions RP2 and second radial line portions LP2 connecting the second annular portions RP2 to each other. The second radial line portions LP2 may be disposed between the second annular portions RP2 facing each other. Because outer sidewalls of the second annular portions RP2 located at the outermost portions face the first annular portions RP1, the second radial line portions LP2 might not be connected to the outer sidewalls of the second annular portions RP2 located at the outermost portions.

A distance between the first annular portions RP1 spaced apart from each other and a distance between the second annular portions RP2 spaced apart from each other may be substantially the same as each other. A distance between the centers of the first annular portions RP1 adjacent to each other may be a first distance D1. A distance between the centers of the second annular portions RP2 adjacent to each other may be a second distance D2. The first distance D1 and the second distance D2 may be substantially the same as each other. A third distance D3 between the centers of the first annular portion and the second annular portion adjacent to each other may be substantially the same as the first distance D1 and/or the second distance D2.

The first and second gate lines GL1 and GL2 may be source select lines, word lines, or drain select lines. For example, a plurality of word lines may be stacked between at least one source select line and at least one drain select line.

According to the structure described above, the first gate line GL1 may include the first annular portions RP1 and the first radial line portions LP1, and the second gate line GL2 may include the second annular portions RP2 and the second radial line portions LP2. Because the radial line portions LP1 and LP2 are not connected to the outer sidewalls OSW of the outermost annular portions RP1 and RP2, the first gate line GL1 and the second gate line GL2 may be separated from each other without a separate slit. This way it is possible to separate the first gate line GL1 and the second gate line GL2 from each other while keeping an interval between the annular portions RP1 and RP2 uniform.

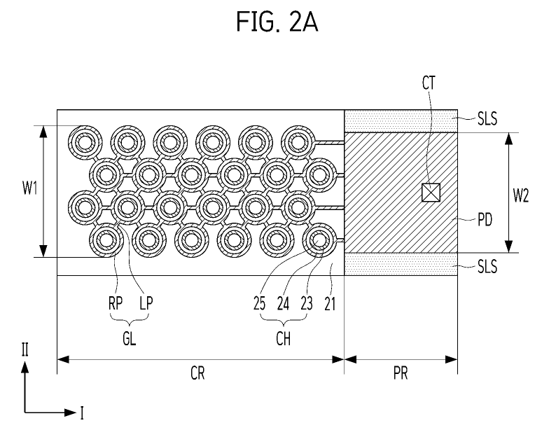

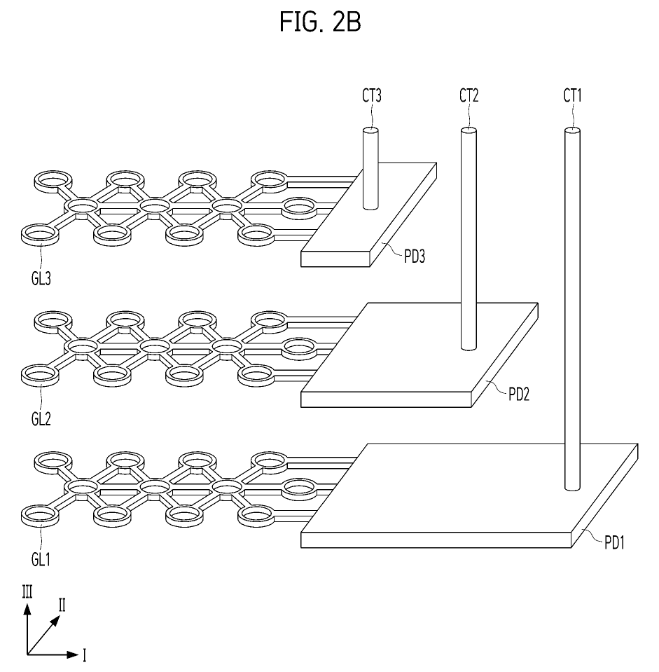

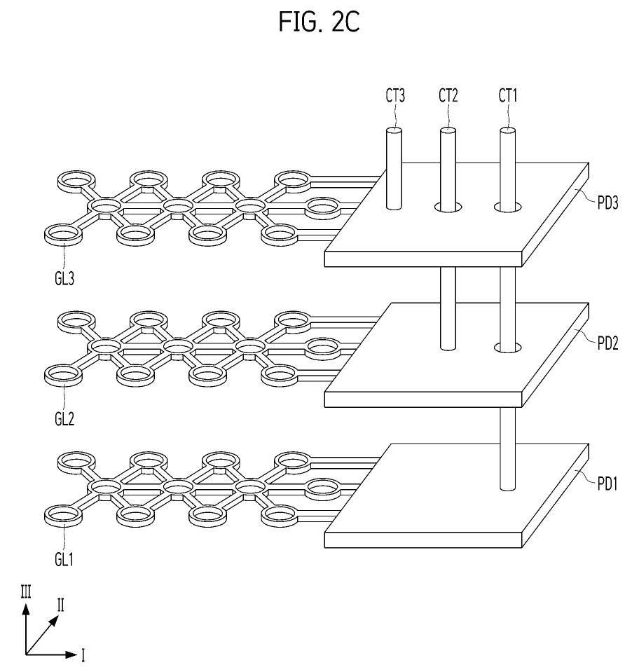

FIGS. 2A to 2C are diagrams illustrating the structure of a semiconductor device in accordance with an embodiment of the present disclosure. Hereinafter, a detailed description of features overlapping with previously described features may be omitted.

Referring to FIG. 2A, the semiconductor device may include a gate line GL and a pad PD. The semiconductor device may further include a channel structure CH, a first insulating layer 21, a contact plug CT, and a slit structure SLS. The first insulating layer 21 may be a portion of the stack ST described with reference to FIGS. 1A to 1C.

The gate line GL, the channel structure CH, and the first insulating layer 21 may be disposed in a cell region CR. The pad PD, the contact plug CT, and the slit structure SLS may be disposed in a pad region PR. The cell region CR is a region where memory cells are stacked. The gate lines GL may be stacked in the cell region CR, and the memory cells may be disposed in regions where channel structures CH and gate lines GL intersect each other. The pad region PR is a region where interconnections for respectively driving the stacked gate lines GL are located. The pads PD may be stacked in the pad region PR, and the contact plugs CT may be connected to the pads PD, respectively.

The gate line GL may include annular portions RP surrounding the channel structures CH and radial line portions LP connecting the annular portions RP to each other. The channel structure CH may include a channel layer 23, a memory layer 24 surrounding the channel layer 23, and an insulating core 25 located in the channel layer 23.

The pad PD may be disposed adjacent to the gate line GL in the first direction I. The pad PD may be electrically connected to the gate line GL, and more specifically to the radial line portions LP of the gate line GL. The pad PD may be disposed between a pair of slit structures SLS, and may have a plate shape. In the second direction II, the gate line GL may have a first width W1, and the pad PD may have a second width W2. The first width W1 and the second width W2 may be different from each other. For example, as shown in FIG. 2A, the second width W2 may be narrower than the first width W1.

Referring to FIGS. 2B and 2C, the semiconductor device may include first to third gate lines GL1 to GL3, first to third pads PD1 to PD3, and first to third contact plugs CT1 to CT3. The first to third pads PD1 to PD3 may be connected to the first to third gate lines GL1 to GL3, respectively. The first to third contact plugs CT1 to CT3 may extend to different depths, and may be connected to the first to third pads PD1 to PD3, respectively.

Referring to FIG. 2B, the first to third pads PD1 to PD3 may be stacked in a staircase shape. The first to third pads PD1 to PD3 may have different lengths in the first direction I. The first pad PD1 may have a longer length than the second pad PD2, and the second pad PD2 may have a longer length than the third pad PD3. The first contact plug CT1 may be connected to a portion of the first pad PD1 that is not covered by the second pad PD2. The second contact plug CT2 may be connected to a portion of the second pad PD2 that is not covered by the third pad PD3.

Referring to FIG. 2C, a different embodiment is shown wherein the first to third pads PD1 to PD3 may have substantially the same length in the first direction I. In this embodiment, the first contact plug CT1 may pass through the second and third pads PD2 and PD3, and may be electrically connected to the first pad PD1. The first contact plug CT1 may be insulated from the second and third pads PD2 and PD3. The second contact plug CT2 may pass through the third pad PD3, and may be electrically connected to the second pad PD2. The second contact plug CT2 may be insulated from the third pad PD3. The third contact plug CT3 may be connected to the third pad PD3.

According to the structure described above, the pads PD may be connected to the gate lines GL, respectively. For example, the first pad PD1 may be connected to the first gate line GL1, the second pad PD2 may be connected to the second gate line GL2, and the third pad PD3 may be connected to the third gate line GL3. By applying driving biases through the contact plugs CT, it is possible to individually drive the gate lines GL. For example, by applying driving biases through the first contact plug CT1 and the first pad PD1 it is possible to individually drive the first gate line GL1.

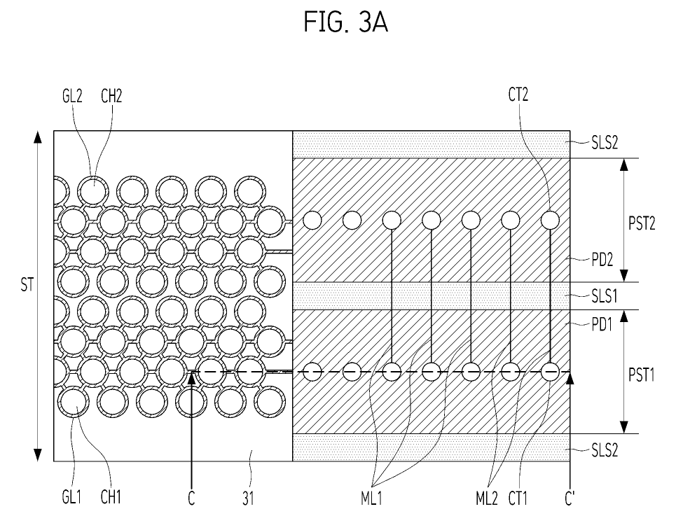

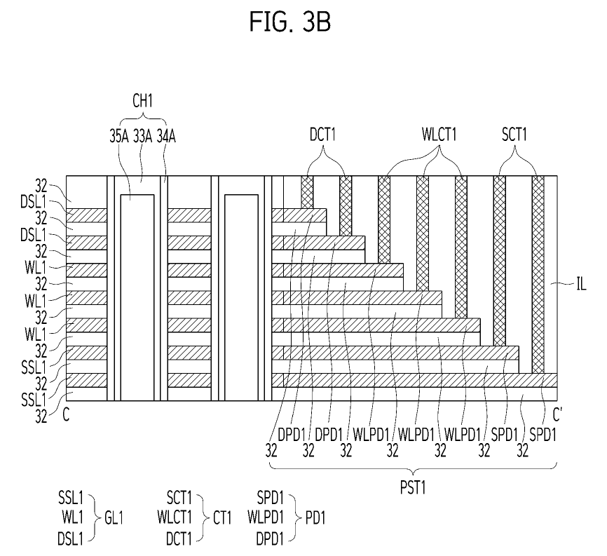

FIGS. 3A and 3B are diagrams illustrating the structure of a semiconductor device in accordance with an embodiment of the present disclosure. FIG. 3A is a plan view. FIG. 3B is a cross-sectional view taken along line C-C’ of FIG. 3A.

Referring to FIGS. 3A and 3B, the semiconductor device may include first gate lines GL1, second gate lines GL2, first channel structures CH1, second channel structures CH2, a stack ST, a first pad stack PST1, a second pad stack PST2, first contact plugs CT1, second contact plugs CT2, a first slit structure SLS1, a second slit structure SLS2, a first wiring line ML1, a second wiring line ML2, and an interlayer insulating layer IL.

The stack ST may include first insulating layers 31 and second insulating layers 32 that are alternately stacked. The first channel structures CH1 and the second channel structures CH2 may extend through the stack ST. The first channel structure CH1 may include a first channel layer 33A, a first memory layer 34A, and a first insulating core 35A.

The first pad stack PST1 may have a staircase shape, and may include first pads PD1 and second insulating layers 32 that are alternately stacked. The second pad stack PST2 may have a staircase shape, and may include second pads PD2 and second insulating layers 32 that are alternately stacked. The stack ST, the first pad stack PST1, and the second pad stack PST2 may share the second insulating layers 32 with each other.

The stack ST and the first pad stack PST1 may be adjacent to each other in the first direction I. Also, the stack ST and the second pad stack PST2 may be adjacent to each other in the first direction I. The first pad stack PST1 and the second pad stack PST2 may be adjacent to each other in the second direction II. At least two pad stacks PST1 and PST2 may be disposed to correspond to one stack ST.

The first and second slit structures SLS1 and SLS2 may be disposed between the first and second pad stacks PST1 and PST2. The first and second slit structures SLS1 and SLS2 may extend in the first direction I. At least one first slit structure SLS1 may be disposed between a pair of second slit structures SLS2. For example, the first slit structure SLS1 may be disposed inside a memory block, and the second slit structure SLS2 may be disposed at a boundary between memory blocks.

The first gate lines GL1 may be stacked along sidewalls of the first channel structures CH1. The stacked first gate lines GL1 may be connected to the first pad stack PST1, and may be connected to the first pads PD1, respectively. The second gate lines GL2 may be stacked along sidewalls of the second channel structures CH2. The stacked second gate lines GL2 may be connected to the second pad stack PST2, and may be connected to the second pads PD2, respectively.

The first gate lines GL1 may be a first source select line SSL1, a first word line WL1, or a first drain select line DSL1. For example, the first gate lines GL1 may include at least one first source select line SSL1, first word lines WL1, and at least one first drain select line DSL1. The first word lines WL1 may be disposed between at least one first source select line SSL1 and at least one first drain select line DSL1.

The first word line WL1, the first drain select line DSL1, and the first source select line SSL1 may have similar shapes. The first word line WL1 may include first annular portions surrounding the first channel structures CH1 and first radial line portions connecting the first annular portions to each other. The first drain select line DSL1 may include third annular portions surrounding the first channel structures CH1 and third radial line portions connecting the third annular portions to each other. The first source select line SSL1 may include fourth annular portions surrounding the first channel structures CH1 and fourth radial line portions connecting the fourth annular portions to each other.

Each of the first word lines WL1 may be connected to a corresponding first word line contact plug WLCT1 through a corresponding first word line pad WLPD1. The first drain select line DSL1 may be connected to a corresponding first drain contact plug DCT1 through a corresponding first drain pad DPD1. The first source select line SSL1 may be connected to a corresponding first source contact plug SCT1 through a corresponding first source pad SPD1. The first word line pads WLPD1, the first drain pad DPD1, and the first source pad SPD1 may be stacked in a staircase shape. The first pad stack PST1 may include a plurality of first drain pads DPD1. Also, the first pad stack PST1 may include a plurality of first source pads SPD1.

The first gate line GL1 and the second gate line GL2 may belong to the same memory block or different memory blocks. When the first and second gate lines GL1 and GL2 belong to the same memory block, the same driving bias may be applied to word lines of the same level. The driving bias may include a program voltage, a pass voltage, a read voltage, or the like. For example, the first word line pad WLPD1 of the first word line WL1 belonging to the first gate line GL1 and a second word line pad of a second word line belonging to the second gate line GL2 may be disposed at the same level, and the first word line contact plug WLCT1 and a second word line contact plug respectively connected to the first word line pad WLPD1 and the second word line pad that are located at the same level may be electrically connected to each other by the first wiring line ML1. Through this, the first word line WL1 and the second word line that are located at the same level may be electrically connected to each other. Similarly, the first source contact plug SCT1 and a second source contact plug respectively connected to the first source pad SPD1 and a second source pad that are located at the same level may be electrically connected to each other by the second wiring line ML2, and the first source select line SSL1 and a second source select line that are located at the same level may be electrically connected to each other. The first and second wiring lines ML1 and ML2 may traverse the first slit structure SLS1, and may extend in the second direction II.

According to the structure described above, the stacked first gate lines GL1 may be connected to the first pad stack PST1, and the stacked second gate lines GL2 may be connected to the second pad stack PST2. A first gate line GL1 and a second gate line GL2 located at the same level may be separated from each other without a slit structure. The first pad PD1 and the second pad PD2 located at the same level may be separated from each other by the first slit structure SLS1. The first pad PD1 and the second pad PD2 located at the same level may be connected to each other using the wiring lines ML1 and ML2.

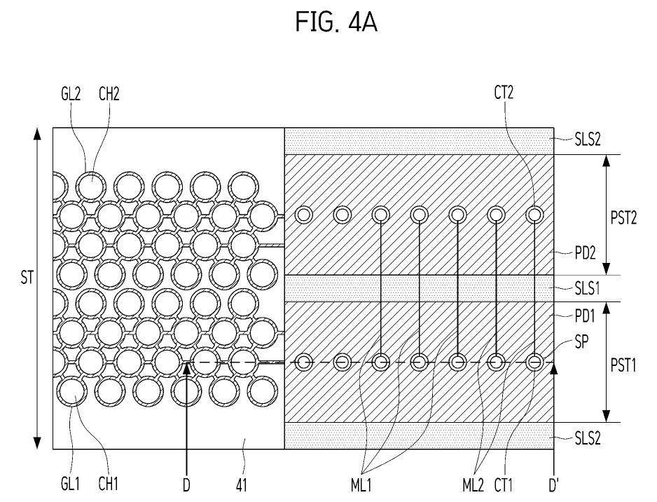

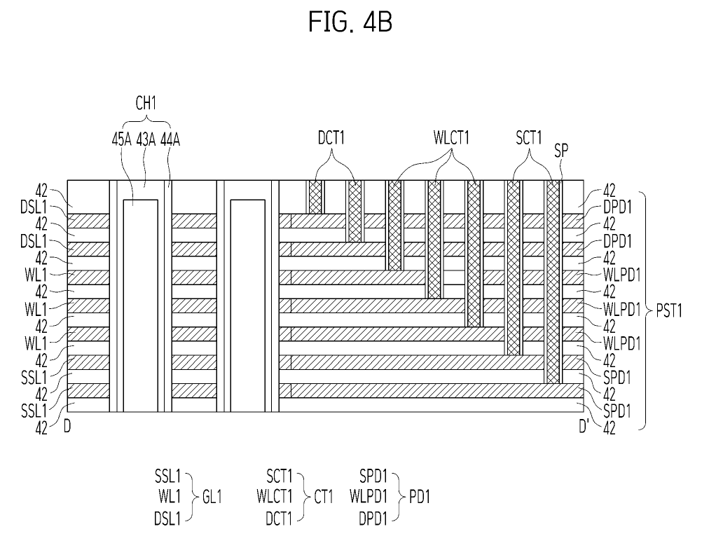

FIGS. 4A and 4B are diagrams illustrating the structure of a semiconductor device in accordance with an embodiment of the present disclosure. FIG. 4A is a plan view, and FIG. 4B is a cross-sectional view taken along line D-D’ of FIG. 4A.

Referring to FIGS. 4A and 4B, the semiconductor device may include first gate lines GL1, second gate lines GL2, first channel structures CH1, second channel structures CH2, a stack ST, a first pad stack PST1, a second pad stack PST2, first contact plugs CT1, second contact plugs CT2, an insulating spacer SP, a first slit structure SLS1, a second slit structure SLS2, a first wiring line ML1, and a second wiring line ML2.

The stack ST may include first insulating layers 41 and second insulating layers 42 that are alternately stacked. The first channel structures CH1 and the second channel structures CH2 may extend through the stack ST. The first channel structure CH1 may include a first channel layer 43A, a first memory layer 44A, and a first insulating core 45A.

The first pad stack PST1 may include first pads PD1 and second insulating layers 42 that are alternately stacked. The second pad stack PST2 may include second pads PD2 and second insulating layers 42 that are alternately stacked. The stack ST, the first pad stack PST1, and the second pad stack PST2 may share the second insulating layers 42 with each other. At least two pad stacks PST1 and PST2 may be disposed to correspond to one stack ST. At least one first slit structure SLS1 may be disposed between a pair of second slit structures SLS2.

The first gate lines GL1 may be stacked along sidewalls of the first channel structures CH1. The stacked first gate lines GL1 may be connected to the first pad stack PST1, and may be connected to the first pads PD1, respectively. The first gate lines GL1 may include at least one first source select line SSL1, first word lines WL1, and at least one first drain select line DSL1. The second gate lines GL2 may be stacked along sidewalls of the second channel structures CH2. The stacked second gate lines GL2 may be connected to the second pad stack PST2, and may be connected to the second pads PD2, respectively. The second gate lines GL1 may include at least one second source select line, second word lines, and at least one second drain select line.

The first pad stack PST1 may include a flat upper surface, and the first contact plugs CT1 may extend at different depths through the first pad stack PST1. A first source contact plug SCT1 may pass through the first drain pad DPD1 and the first word line pad WLPD1, to connect to the first source pad SPD1. Sidewalls of the first source contact plug SCT1 may be surrounded by the insulating spacer SP. The first source contact plug SCT1 may be insulated from the first drain pad DPD1 and the first word line pad WLPD1 by the insulating spacer SP. First word line contact plugs WLCT1 may pass through the first drain pad DPD1, and may each be connected to a corresponding one of the first word line pads WLPD1, respectively. Sidewalls of the first word line contact plugs WLCT1 may be surrounded by the insulating spacers SP. The first word line contact plugs WLCT1 may be insulated by the insulating spacers SP from the first drain pad DPD1 and from one or more of the first word line pads WLPD1 that they pass through and are not supposed to electrically connect with.

The second pad stack PST2 may include a flat upper surface, similar to the first pad stack PST1. The second contact plugs CT2 may extend at different depths through the second pad stack PST2.

The first gate line GL1 and the second gate line GL2 may belong to the same memory block or different memory blocks. A first word line pad WLPD1 of the first word line WL1 belonging to the first gate line GL1 and a second word line pad of a second word line belonging to the second gate line GL2 may be disposed at the same level, and the first word line contact plug WLCT1 and a second word line contact plug respectively connected to the first word line pad WLPD1 and the second word line pad that are located at the same level may be electrically connected to each other by the first wiring line ML1. Similarly, the first source contact plug SCT1 and a second source contact plug respectively connected to a first source pad SPD1 and a second source pad that are located at the same level may be electrically connected to each other by the second wiring line ML2.

According to the structure described above, the stacked first gate lines GL1 may be connected to the first pad stack PST1, and the stacked second gate lines GL2 may be connected to the second pad stack PST2. The first gate line GL1 and the second gate line GL2 that are located at the same level may be separated from each other without a slit structure. The first pad PD1 and the second pad PD2 that are located at the same level may be separated from each other by the first slit structure SLS1. The first pad PD1 and the second pad PD2 that are located at the same level may be connected to each other using the wiring lines ML1 and ML2.

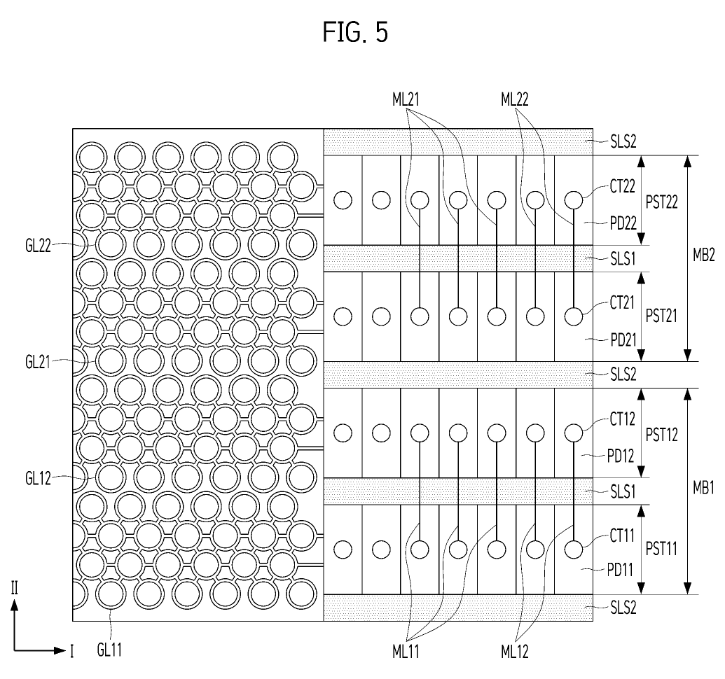

FIG. 5 is a diagram illustrating the structure of a semiconductor device in accordance with an embodiment of the present disclosure.

Referring to FIG. 5, the semiconductor device may include a first memory block MB1 and a second memory block MB2. A memory block may be a unit of an erase operation. The first memory block MB1 may include a first gate line GL11, a second gate line GL12, a first pad stack PST11, a second pad stack PST12, first contact plugs CT11, and second contact plugs CT12. The first gate line GL11 and the second gate line GL12 that are located at the same level may be separated from each other. The first gate lines GL11 may be connected to first pads PD11, respectively, and the first pads PD11 may be connected to the first contact plugs CT11, respectively. The second gate lines GL12 may be connected to second pads PD12, respectively, and the second pads PD12 may be connected to the second contact plugs CT12, respectively.

The second memory block MB2 may include a first gate line GL21, a second gate line GL22, a first pad stack PST21, a second pad stack PST22, first contact plugs CT21, and second contact plugs CT22. The first gate line GL21 and the second gate line GL22 that are located at the same level may be separated from each other. The first gate lines GL21 may be connected to first pads PD21, respectively, and the first pads PD21 may be connected to the first contact plugs CT21, respectively. The second gate lines GL22 may be connected to second pads PD22, respectively, and the second pads PD22 may be connected to the second contact plugs CT22, respectively.

The first and second memory blocks MB1 and MB2 may be adjacent to each other along the second direction II. The second gate line GL12 of the first memory block MB1 and the first gate line GL21 of the second memory block MB2 may be adjacent to each other in the second direction II. Importantly, a slit structure might not be located between the second gate line GL12 and the first gate line GL21, however, the second gate line GL12 and the first gate line GL21 that are located at the same level are electrically separated from each other without a slit structure.

At a boundary between the first and second memory blocks MB1 and MB2, a second slit structure SLS2 is disposed between the second pad stack PST12 of the first memory block MB1 and the first pad stack PST21 of the second memory block MB2. The second pad stack PST12 of the first memory block MB1 and the first pad stack PST21 of the second memory block MB2 may be separated from each other by the second slit structure SLS2. However, the second slit structure SLS2 might not be located between the second gate line GL12 and the first gate line GL21.

A first wiring line ML11 may be used to connect word lines located at the same level among the first and second gate lines GL11 and GL12 to each other in the first memory block MB1. A second wiring line ML12 may be used to connect source select lines located at the same level among the first and second gate lines GL11 and GL12 to each other in the first memory block MB1. A second wiring line ML21 may be used to connect word lines located at the same level among the first and second gate lines GL21 and GL22 to each other in the second memory block MB2. A second wiring line ML22 may be used to connect source select lines located at the same level among the first and second gate lines GL21 and GL22 to each other in the second memory block MB2.

According to the structure described above, the first gate line GL11 and the second gate line GL12 belonging to the first memory block MB1 may be separated from each other without a separate slit structure. The second gate line GL12 belonging to the first memory block MB1 and the first gate line GL21 belonging to the second memory block MB2 may be separated from each other without a separate slit structure.

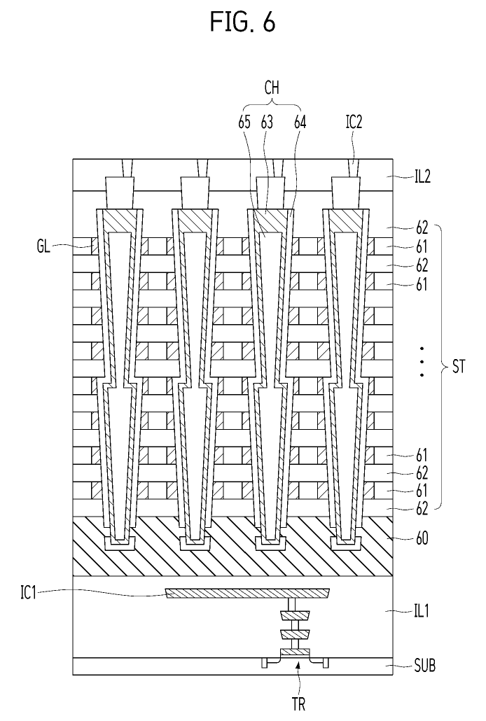

FIG. 6 is a diagram illustrating the structure of a semiconductor device in accordance with an embodiment of the present disclosure. Hereinafter, a detailed description of features overlapping with previously described features may be omitted.

Referring to FIG. 6, the semiconductor device may include a substrate SUB, a transistor TR, a first interconnection structure IC1, a first interlayer insulating layer IL1, a source structure 60, gate lines GL, a stack ST, a channel structure CH, a second interconnection structure IC2, and a second interlayer insulating layer IL2. A peripheral circuit may be disposed below a memory cell array.

The transistor TR may be disposed on the substrate SUB. The transistor TR may belong to the peripheral circuit. For example, the peripheral circuit may include a row decoder, a page buffer, an input/output circuit, a logic circuit, and the like. The first interconnection structure IC1 may be formed in the first interlayer insulating layer IL1, and may be electrically connected to the peripheral circuit. The first interconnection structure IC1 may include a via, a wiring line, and the like.

The source structure 60 may be disposed on the first interlayer insulating layer IL1, and the stack ST may be disposed on the source structure 60. The stack ST may include first insulating layers 61 and second insulating layers 62 that are alternately stacked. The channel structures CH may extend through the stack ST, and may be connected to the source structure 60. Each of the channel structures CH may include a channel layer 63, a memory layer 64, and an insulating core 65. The gate lines GL may be stacked along sidewalls of the channel structures CH. The gate line GL may each include annular portions surrounding the channel structures CH and radial line portions connecting the annular portions to each other.

The second interconnection structure IC2 may be disposed in the second interlayer insulating layer IL2, and may be connected to the channel structure CH or the like. The second interconnection structure IC2 may include a via, a wiring line, and the like.

According to the structure described above, by locating the peripheral circuit below the memory cell array, it is possible to increase the degree of integration of the semiconductor device. In addition, the gate line GL includes the annular portions and the radial line portions, and it is thus possible to separate the gate lines GL located at the same level from each other without a slit structure.

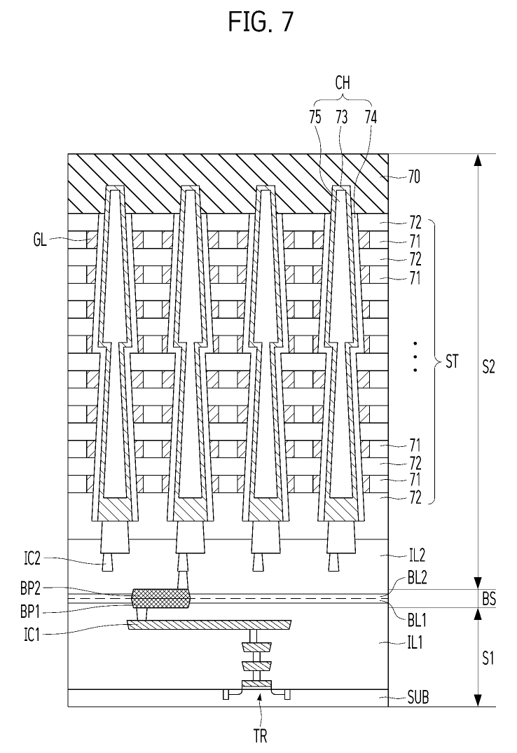

FIG. 7 is a diagram illustrating the structure of a semiconductor device in accordance with an embodiment of the present disclosure. Hereinafter, a detailed description of features overlapping with previously described features may be omitted.

Referring to FIG. 7, the semiconductor device may include a first semiconductor structure S1, a second semiconductor structure S2, and a bonding structure BS connecting the first and second semiconductor structures S1 and S2. For example, the first semiconductor structure S1 may include a peripheral circuit, and the second semiconductor structure S2 may include a memory cell array.

For example, the first semiconductor structure S1 may include a substrate SUB, a transistor TR, a first interlayer insulating layer IL1, and a first interconnection structure IC1. The transistor TR may be a part of the peripheral circuit. The first interconnection structure IC1 may be disposed in the first interlayer insulating layer IL1, and may include a via, a wiring line, and other conductive pathways. The first interconnection structure IC1 may be electrically connected to the peripheral circuit and facilitate electrical connection linking the peripheral circuit to other parts of the semiconductor device.

The second semiconductor structure S2 may include a source structure 70, a stack ST, a channel structure CH, a second interlayer insulating layer IL2, and a second interconnection structure IC2. The stack ST may include first insulating layers 71 and second insulating layers 72 that are alternately stacked. The source structure 70 may be disposed above or below the stack ST. The channel structure CH may extend through the stack ST, and may be connected to the source structure 70. The channel structure CH may extend partially into the source structure 70. The channel structure CH may include a channel layer 73, a memory layer 74, and an insulating core 75. Gate lines GL may be stacked along sidewalls of the channel structures CH. The gate lines GL may include annular portions surrounding the channel structures CH and radial line portions connecting the annular portions to each other.

The bonding structure BS may be disposed between the first semiconductor structure S1 and the second semiconductor structure S2. The first semiconductor structure S1 and the second semiconductor structure S2 may be manufactured separately, and may be electrically connected to each other by the bonding structure BS. The memory cell array including the gate lines GL and the peripheral circuit including the transistor TR may be electrically connected to each other through the bonding structure BS.

The bonding structure BS may include a first bonding layer BL1, a second bonding layer BL2, a first bonding pad BP1, and a second bonding pad BP2. The first bonding layer BL1 and the second bonding layer BL2 may contact each other. Also, the first and second bonding pads BP1 and BP2 may contact each other. In an embodiment, the first bonding layer BL1 and the second bonding layer BL2 may each include SiCN (silicon carbonitride), tetra ethyl ortho silicate (TEOS), or the like. The first bonding pad BP1 may be electrically connected to the first interconnection structure IC1, and the second bonding pad BP2 may be electrically connected to the second interconnection structure IC2. Accordingly, the memory cell array and the peripheral circuit may be electrically connected to each other through the first bonding pad BP1 and the second bonding pad BP2.

According to the structure described above, first and second semiconductor structures S1 and S2 are bonded to each other in a vertical direction resulting in significantly increased degree of integration of the overall semiconductor device. In addition, the gate line GL includes the annular portions and the radial line portions, and it is thus possible to separate the gate lines GL located at the same layer from each other without a slit structure, thus further reducing the space requirements of the semiconductor device.

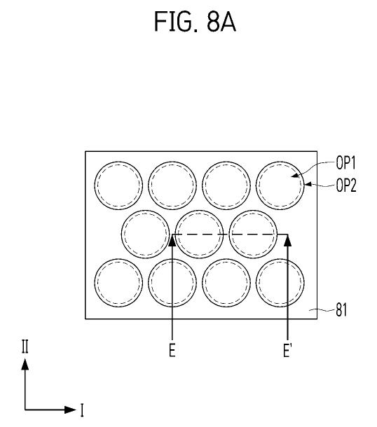

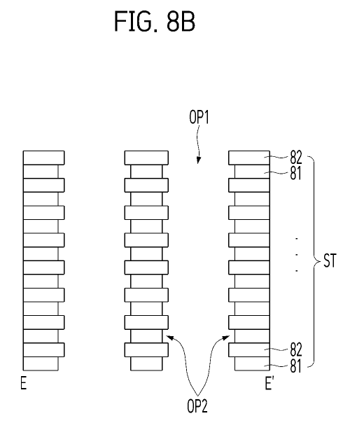

FIGS. 8A, 9A, 10A, 11A, 12A, and 13A and FIGS. 8B, 9B, 10B, 11B, 12B, and 13B are diagrams for describing a method of manufacturing a semiconductor device in accordance with an embodiment of the present disclosure. FIGS. 8A, 9A, 10A, 11A, 12A, and 13A are plan views, and FIGS. 8B, 9B, 10B, 11B, 12B, and 13B are cross-sectional views taken along lines E-E’ of FIGS. 8A, 9A, 10A, 11A, 12A, and 13A, respectively.

Referring to FIGS. 8A and 8B, a stack ST may be formed including first and second insulating layers 81 and 82 that are alternately stacked. The first insulating layers 81 may each include a material having a high etching selectivity with respect to the second insulating layers 82. For example, the first insulating layers 81 may each include a nitride, and the second insulating layers 82 may each include an oxide.

Subsequently, first openings OP1 extending through the stack ST may be formed. The first openings OP1 may be used as passages for forming gate lines, and may be channel holes in which channel structures are to be formed in a subsequent process. Subsequently, second openings OP2 may be formed by etching the first insulating layers 81 through the first openings OP1. The second openings OP2 may surround the first openings OP1.

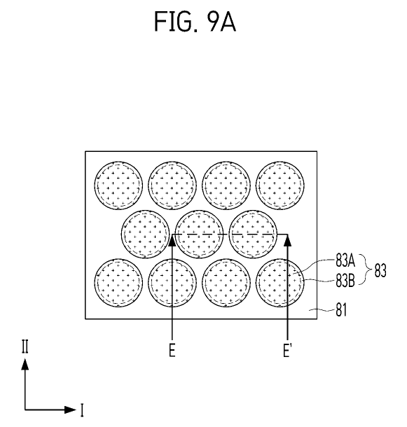

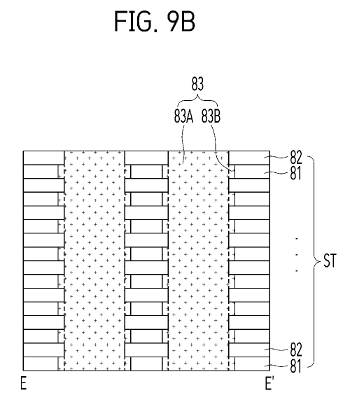

Referring to FIGS. 9A and 9B, sacrificial layers 83 may be formed in the first openings OP1 and the second openings OP2. The first openings OP1 and the second openings OP2 may be filled by the sacrificial layers 83. The sacrificial layers 83 may include a first portion 83A located in the first opening OP1 and second portions 83B located in the second openings OP2. The sacrificial layers 83 may each include a material having a high etching selectivity with respect to the first and second insulating layers 81 and 82. For example, the sacrificial layers 83 may each include a carbon layer and/or a tungsten layer.

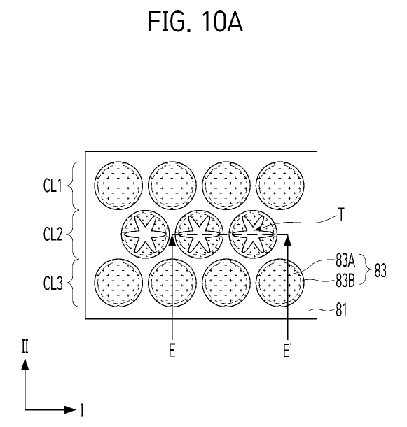

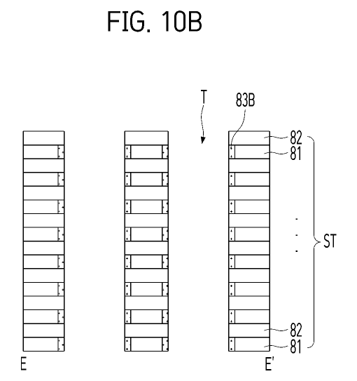

Referring to FIGS. 10A and 10B, at least one trench T may be formed in at least one sacrificial layer 83 of the sacrificial layers 83. The sacrificial layers 83 arranged in the first direction I may constitute one column, and trenches T may be formed only in the sacrificial layers 83 arranged in some of a plurality of columns. For example, the sacrificial layers 83 may be grouped into first to third columns CL1 to CL3. The sacrificial layers 83 belonging to the first column CL1 may be arranged along the first direction I. The sacrificial layers 83 belonging to the second column CL2 may be staggered with respect to the sacrificial layers 83 of the first column CL1. The sacrificial layers 83 belonging to the third column CL3 may be staggered with respect to the sacrificial layers 83 of the second column CL2. When a gate line is to be formed by connecting the first to third columns CL1 to CL3 to each other, the trenches T may be formed only in the sacrificial layers 83 belonging to the second column CL2 excluding the first and third columns CL1 and CL3 located at edges.

One trench T may be formed in one sacrificial layer 83. The trench T may have a radial shape extending from the center of the sacrificial layer 83 toward the surrounding sacrificial layers 83. For example, six sacrificial layers 83 may be disposed around one sacrificial layer 83, and the trench T may have a shape extending in six directions from the center of the sacrificial layer 83. The trench T may be disposed in the first portion 83A within the sacrificial layer 83, and might not be located in the second portion 83B within the sacrificial layer 83. In a plan view, the second portions 83B may be exposed through ends of the trench T extending toward the surrounding sacrificial layers 83.

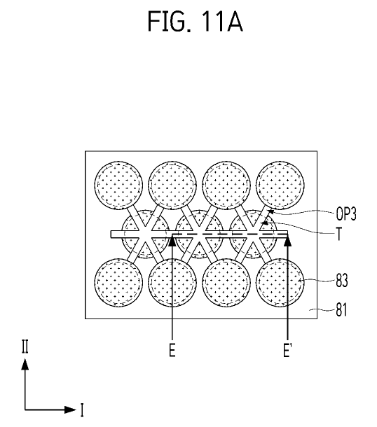

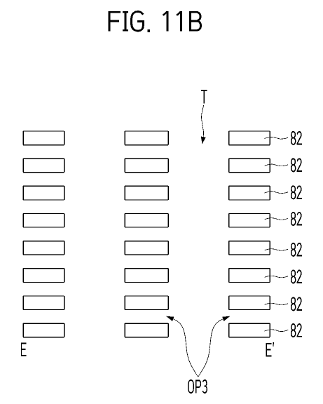

Referring to FIGS. 11A and 11B, the first insulating layers 81 may be exposed by etching the sacrificial layer 83 through the trench T. The second portions 83B may be selectively etched through the trench T, and the first insulating layers 81 may be partially exposed. Subsequently, the surrounding sacrificial layers 83 may be exposed by selectively etching the first insulating layer 81. Through this, third openings OP3 connecting the second openings OP2 to each other may be formed, and the second portions 83B of the surrounding sacrificial layers 83 may be exposed through the third openings OP3.

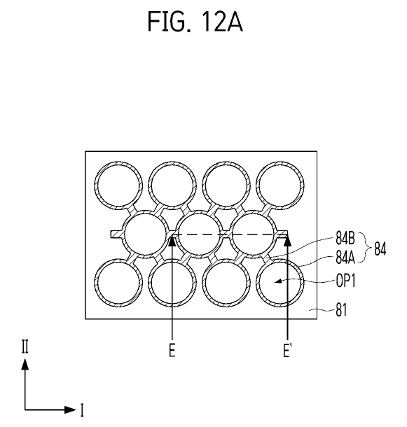

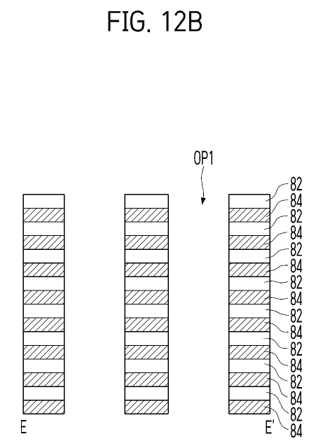

Referring to FIGS. 12A and 12B, the sacrificial layers 83 may be removed. Through this, the first and second openings OP1 and OP2 may be reopened, and the second openings OP2 may be connected to each other through the third openings OP3.

Subsequently, gate lines 84 may be formed in the second openings OP2 and the third openings OP3. The gate lines 84 may be formed by depositing a conductive layer in the second openings OP2 and the third openings OP3 through the first opening OP1 and etching a portion of the conductive layer formed in the first opening OP1. The gate line 84 may include annular portions 84A located in the second openings OP2 and line portions 84B located in the third openings OP3. The annular portions 84A may be connected to each other by the line portions 84B. The line portions 84B may connect the annular portions 84A to each other in a radial shape. The gate lines 84 may each include metal such as tungsten or molybdenum.

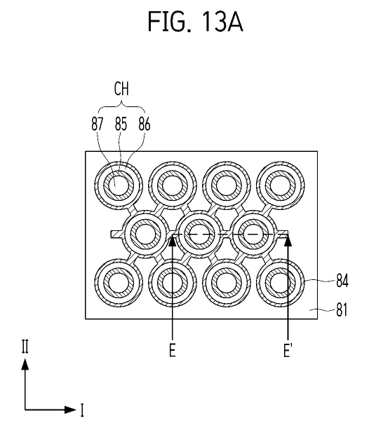

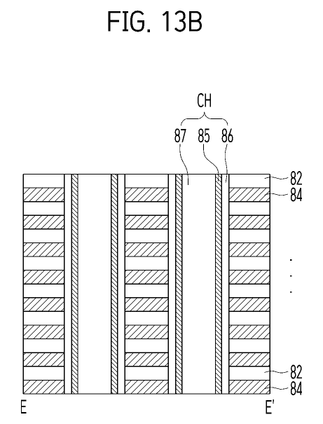

Referring to FIGS. 13A and 13B, channel structures CH may be formed in the first openings OP1. A memory layer 86, a channel layer 85, and an insulating core 87 may be formed in each of the first openings OP1. For example, a first blocking layer may be formed in each of the first openings OP1, a second blocking layer, a data storage layer, and a tunneling layer may be formed on the first blocking layer, and the channel layer 85 may be formed on the tunneling layer.

According to the method described above, the first and second openings OP1 and OP2 may be formed using the channel hole, and the third openings OP3 connecting the second openings OP2 to each other may be formed using the trench T. Through this, the gate lines 84 including the annular portions 84A and the line portions 84B connecting the annular portions 84A to each other may be formed. The annular portions 84A that are connected to each other by the line portions 84B may form one gate line 84, and the annular portions 84A that are not connected to each other by the line portions 84B belong to different gate lines 84. Accordingly, it is possible to form gate lines 84 separated from each other without a slit structure.

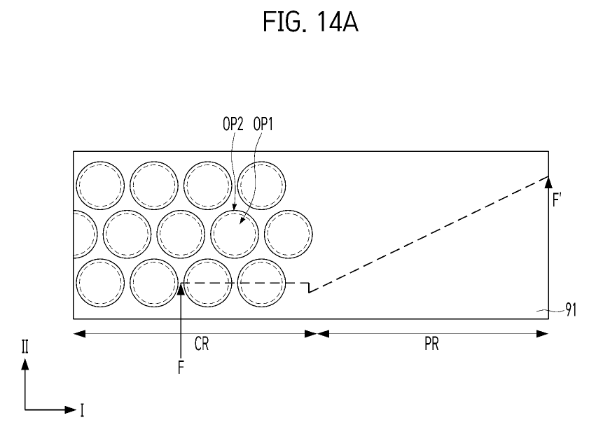

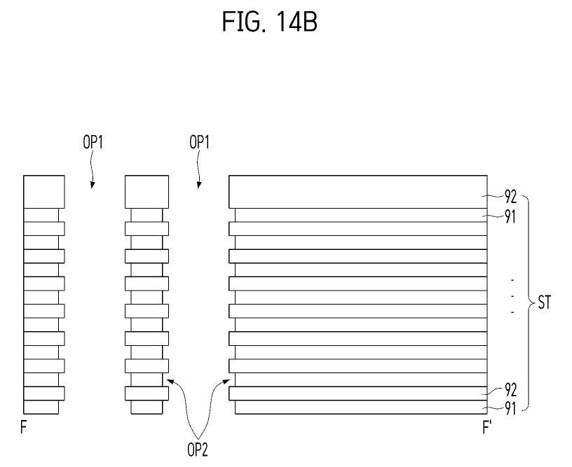

FIGS. 14A, 15A, 16A, 17A, and 18A and FIGS. 14B, 15B, 16B, 17B, and 18B are diagrams for describing a method of manufacturing a semiconductor device in accordance with an embodiment of the present disclosure. FIGS. 14A, 15A, 16A, 17A, and 18A are plan views, and FIGS. 14B, 15B, 16B, 17B, and 18B are cross-sectional views taken along lines F-F’ of FIGS. 14A, 15A, 16A, 17A, and 18A, respectively.

Referring to FIGS. 14A and 14B, a stack ST may be formed including first and second insulating layers 91 and 92 that are alternately stacked. The stack ST may include a cell region CR and a pad region PR.

Subsequently, first openings OP1 extending through the cell region CR of the stack ST may be formed. Subsequently, second openings OP2 may be formed by etching the first insulating layers 91 through the first openings OP1. The second openings OP2 may surround the first openings OP1.

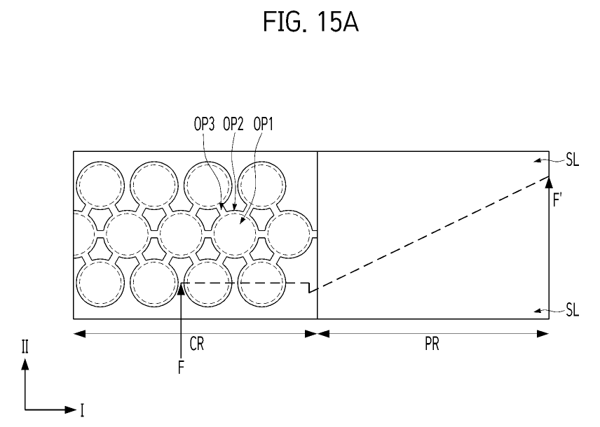

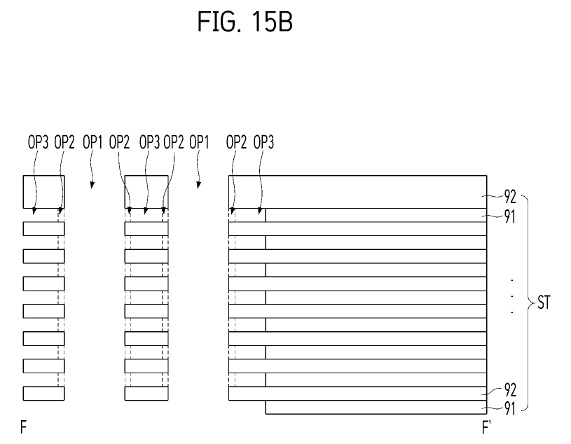

Referring to FIGS. 15A and 15B, third openings OP3 connecting adjacent second openings OP2 to each other may be formed by etching the first insulating layers 91 through the second openings OP2. For example, the third openings OP3 may be formed by forming sacrificial layers in the first and second openings OP1 and OP2, forming trenches in the sacrificial layers, and etching the sacrificial layers and the first insulating layers 91 through the trenches.

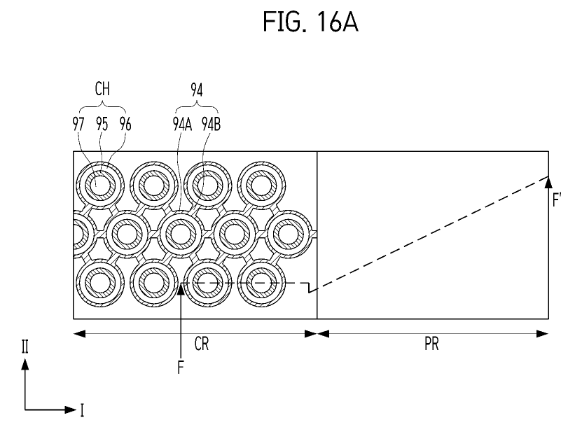

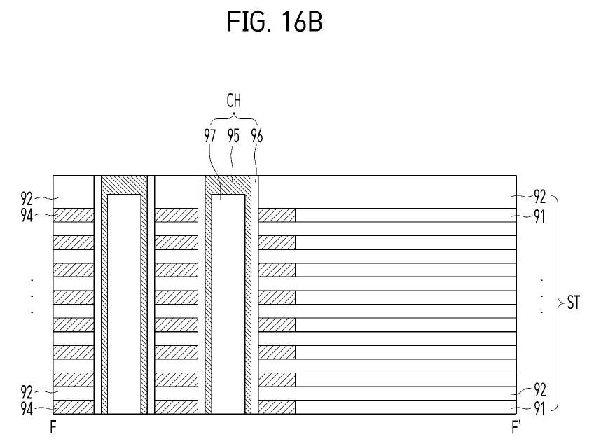

Referring to FIGS. 16A and 16B, gate lines 94 may be formed in the second openings OP2 and the third openings OP3. The gate lines 94 may include annular portions 94A located in the second openings OP2 and line portions 94B located in the third openings OP3. The line portions 94B may connect the annular portions 94A to each other in a radial shape. Subsequently, channel structures CH may be formed in the first openings OP1. A memory layer 96, a channel layer 95, and an insulating core 97 may be formed in each of the first openings OP1.

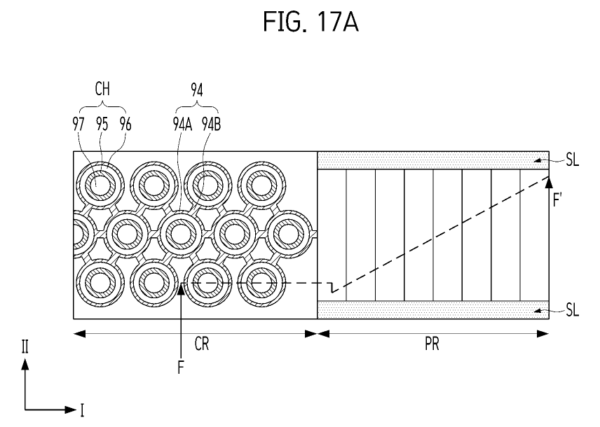

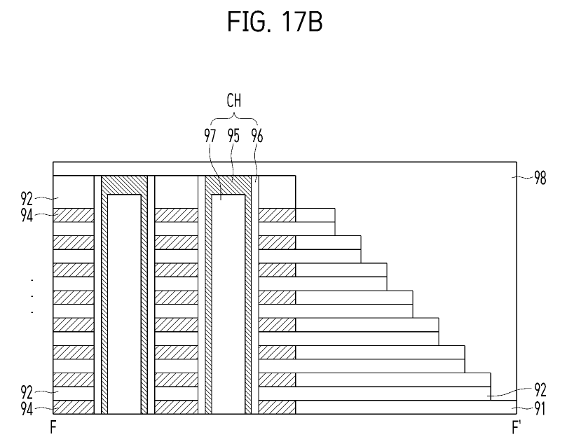

Referring to FIGS. 17A and 17B, the stack ST may be patterned in a staircase shape. For example, a mask pattern may be formed on the stack ST, and the stack ST may be etched using the mask pattern as an etching barrier. By repeatedly reducing the size of the mask and performing selective etching in a controlled manner, the desired staircase structure is progressively developed with precision. This method ensures that the stack achieves the intended shape while maintaining its structural integrity and design requirements. Subsequently, an interlayer insulating layer 98 may be formed on the stack ST.

Subsequently, a slit SL may be formed in the pad region PR of the stack ST. The slit SL may extend along the first direction I, and might not be formed in the cell region CR.

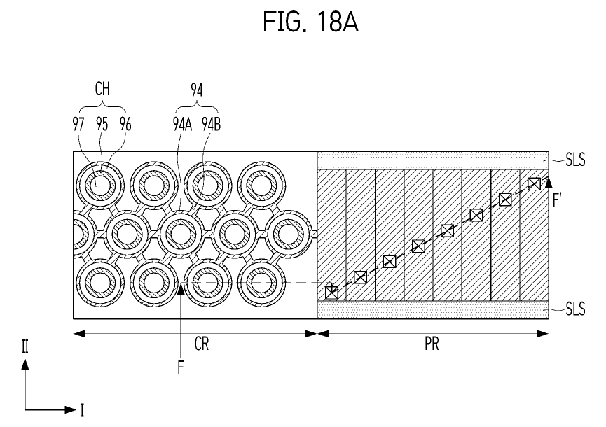

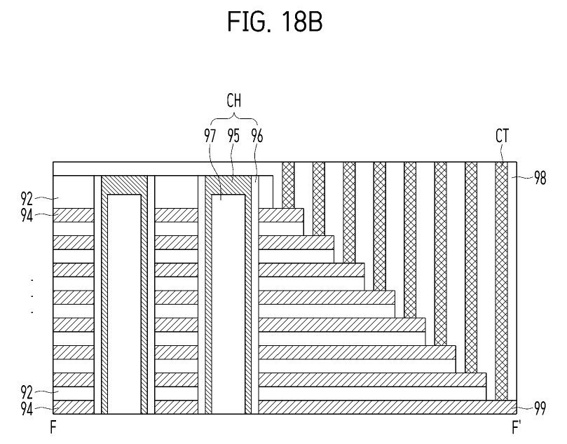

Referring to FIGS. 18A and 18B, the first insulating layers 91 may be replaced with pads 99 through the slit SL. For example, the first insulating layers 91 may be removed through the slit SL, and conductive layers may be formed in regions where the first insulating layers 91 are removed. The conductive layers may each include metal such as tungsten or molybdenum. Through this, the pads 99 respectively connected to the gate lines 94 may be formed. Subsequently, a slit structure SLS may be formed in the slit.

Subsequently, contact plugs CT respectively connected to the pads 99 may be formed. The contact plugs CT may extend at different depths through the interlayer insulating layer 98. Subsequently, a wiring line connecting the contact plugs CT connected to the pads 99 located at the same level to each other may be formed.

For reference, a case where the stack ST is patterned in the staircase shape has been described in the present embodiment, but the embodiments are not limited thereto. It is also possible to keep an upper portion of the stack ST flat and form the contact plugs CT to extend through the stack ST. A case where the pads 99 are formed after the gate lines 94 are formed has been described in the present embodiment, but the embodiments are not limited thereto, and the process order described above may be changed. For example, it is also possible to form the pads 99 before forming the gate lines 94.

According to the method described above, the gate lines 94 may be formed using a channel hole, and may be separated from each other without a slit structure. In addition, by forming the slit only in the pad region PR, it is possible to form the pads 99 respectively connected to the gate lines 94.

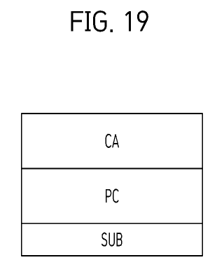

FIG. 19 is a configuration diagram of a semiconductor device according to an embodiment of the present disclosure.

Referring to FIG. 19, the semiconductor device may include a substrate SUB, a peripheral circuit PC, and a memory cell array CA. Here, the peripheral circuit PC and the memory cell array CA may be formed on the same substrate.

The substrate SUB may be made of or include a semiconductor material. In an embodiment, the semiconductor material may include at least one of a group IV semiconductor, a group III-V compound semiconductor, and a group II-VI compound semiconductor. Here, the group IV semiconductor may include single crystal silicon Si, polycrystalline silicon, germanium Ge, or silicon germanium SiGe. The group III-V compound semiconductor can consist of various materials, including gallium arsenide (GaAs), gallium nitride (GaN), gallium phosphide (GaP), gallium arsenide phosphide (GaAsP), gallium indium arsenide phosphide (GaInAsP), aluminum arsenide (AlAs), aluminum gallium (AlGa), indium phosphide (InP), indium antimonide (InSb), or indium gallium arsenide (InGaAs). The group II-VI compound semiconductors may include materials such as zinc sulfide (ZnS), zinc oxide (ZnO), or cadmium sulfide (CdS).

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be disposed between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a PMOS transistor, a resistor, a capacitor, and the like. The peripheral circuit PC may further include an interconnection structure. The interconnection structure may be used as a path for transferring an operation voltage, and may include a contact plug, a line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

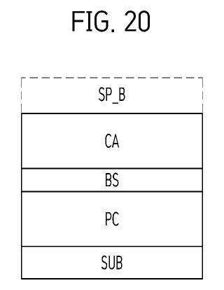

FIG. 20 is a configuration diagram of a semiconductor device according to an embodiment of the present disclosure.

Referring to FIG. 20, the semiconductor device may include a substrate SUB, a peripheral circuit PC, a bonding structure BS, and a memory cell array CA. Here, the peripheral circuit PC and the memory cell array CA may be respectively formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS.

For reference, an interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this, contact plugs, lines, and the like formed on different wafers may be electrically connected without a separate bonding pad.

Other embodiments may be equal or similar to those described above with reference to FIG. 19.

Furthermore, the semiconductor device may have a structure in which the embodiments described above with reference to FIGS. 19 and 20 are combined or may have a partially modified structure. In the embodiment described with reference to FIGS. 19 and 20, positions of the memory cell array CA and the peripheral circuit PC may be changed. At least one memory cell array CA and/or at least one peripheral circuit PC may be additionally bonded to the embodiment described with reference to FIGS. 19 and 20. In an embodiment, a portion of the peripheral circuitry PC may be disposed in the memory cell array CA.

Although embodiments according to the technical concepts of the present disclosure have been described above with reference to the accompanying drawings, this is only for describing the embodiments according to the concept of the present disclosure, and the scope of the present disclosure is not limited to the above embodiments. Various types of substitutions, modifications, changes, and combinations for the embodiments may be made by those skilled in the art, to which the present disclosure pertains, without departing from the technical concepts of the present disclosure defined in the following claims, and it should be construed that these substitutions, modifications, changes, and combinations belong to the scope of the present disclosure. Furthermore, the embodiments may be combined to from additional embodiments.

What is claimed is:

1. A semiconductor device comprising:
a stack including first insulating layers and second insulating layers that are alternately stacked;
channel structures extending through the stack; and
gate lines disposed between the channel structures and the first insulating layers and including annular portions respectively surrounding the channel structures and line portions connecting the annular portions to each other.

2. The semiconductor device of claim 1, wherein the line portions connect the annular portions to each other in a radial shape.

3. The semiconductor device of claim 1, further comprising:
a pad stack including pads alternately stacked with the second insulating layers; and
contact plugs respectively connected to the pads,
wherein the pads and the gate lines are connected to each other, respectively.

4. The semiconductor device of claim 3, wherein the pads are stacked in a staircase shape.

5. The semiconductor device of claim 3, wherein the pad stack includes a flat upper surface, and the contact plugs extend at different depths through the pad stack.

6. The semiconductor device of claim 1, wherein the gate lines comprise:
at least one source select line;
at least one drain select line; and
word lines stacked between the at least one source select line and the at least one drain select line.

7. A semiconductor device comprising:
first channel structures arranged in a first direction and a second direction intersecting the first direction;
first word lines including first annular portions respectively surrounding the first channel structures and first line portions connecting the first annular portions to each other and stacked along sidewalls of the first channel structures;
second channel structures arranged in the first direction and the second direction;
second word lines including second annular portions respectively surrounding the second channel structures and second line portions connecting the second annular portions to each other and stacked along sidewalls of the second channel structures;
a first pad stack including first word line pads connected to the first word lines; and
a second pad stack including second word line pads connected to the second word lines.

8. The semiconductor device of claim 7, wherein a distance between centers of the first channel structures is a first distance, a distance between centers of the second channel structures is a second distance, a distance between centers of the first channel structure and the second channel structure adjacent to each other is a third distance, and the third distance is substantially the same as the first distance.

9. The semiconductor device of claim 8, wherein the first distance, the second distance, and the third distance are substantially the same as each other.

10. The semiconductor device of claim 7, wherein a distance between centers of the first annular portions is a first distance, a distance between centers of the second annular portions is a second distance, a distance between centers of the first annular portion and the second annular portion adjacent to each other is a third distance, and the third distance is substantially the same as the first distance.

11. The semiconductor device of claim 10, wherein the first distance, the second distance, and the third distance are substantially the same as each other.

12. The semiconductor device of claim 9, further comprising:
first word line contact plugs respectively connected to the first word line pads; and
second word line contact plugs respectively connected to the second word line pads.

13. The semiconductor device of claim 12, wherein the first pad stack includes a flat upper surface, and the first word line contact plugs extend at different depths through the first pad stack.

14. The semiconductor device of claim 12, further comprising a wiring line connecting a first word line contact plug and a second word line contact plug respectively connected to a first word line pad and a second word line pad that are disposed at the same level to each other.

15. The semiconductor device of claim 7, wherein the first word line pads are stacked in a staircase shape.

16. The semiconductor device of claim 7, further comprising a slit structure disposed between the first pad stack and the second pad stack.

17. The semiconductor device of claim 7, wherein the first word lines and the second word lines belong to the same memory block, and a first word line and a second word line that are disposed at the same level are electrically connected to each other.

18. The semiconductor device of claim 7, wherein the first word lines and the second word lines belong to different memory blocks, and a first word line and a second word line that are disposed at the same level are electrically separated from each other.

19. The semiconductor device of claim 7, further comprising a first drain select line including third annular portions respectively surrounding the first channel structures and third line portions connecting the third annular portions to each other.

20. The semiconductor device of claim 19, wherein the first pad stack further includes a first drain pad connected to the first drain select line.

21. The semiconductor device of claim 7, further comprising a first source select line including fourth annular portions respectively surrounding the first channel structures and fourth line portions connecting the fourth annular portions to each other.

22. The semiconductor device of claim 21, wherein the first pad stack further includes a first source pad connected to the first source select line.
